(19) United States
(12) Patent Application Publication
(10) Pub. No.: US 2010/0200880 A1
(43) Pub. Date: Aug. 12, 2010

(54) SEMICONDUCTOR WAFERS AND SEMICONDUCTOR DEVICES AND METHODS OF MAKING SEMICONDUCTOR WAFERS AND DEVICES

(75) Inventors: Ping Sit, Hong Kong (CN); Shu Yuan, Hong Kong (CN)

Correspondence Address: VENABLE LLP, P.O. BOX 34385, WASHINGTON, DC, 20043-9998, US

(73) Assignee: Hong Kong Applied Science and Technology Research Institute Co. Ltd., Hong Kong (CN)

(21) Appl. No.: 12/648,782

(22) Filed: Dec. 29, 2009

Related U.S. Application Data
(63) Continuation-in-part of application No. 12/134,682, filed on Jun. 6, 2008.

(51) Int. Cl. H01L 33/58; H01L 21/20

(52) U.S. Cl. 257/98; 438/478; 257/E33.068; 257/E21.09

(57) ABSTRACT

Semiconductor wafers, semiconductor devices, and methods of making semiconductor wafers and devices are provided. Embodiments of the present invention are especially suitable for use with substrate substitution applications, such in the case of fabricating vertical LED. One embodiment of the present invention includes a method of making a semiconductor device, the method comprising providing a substrate; forming a plurality of polishing stops on the substrate, each of the plurality of polishing stops including ceramic material; growing one or more buffer layers on the substrate; and growing one or more epitaxial layers on the one or more buffer layers. Additionally, the steps of applying one or more metal layers to the one or more epitaxial layers, affixing a second substrate to the one or more metal layers and removing the base substrate using a mechanical thinning process may be performed.

### CROSS-REFERENCE TO RELATED APPLICATIONS

This application is a continuation-in-part of U.S. patent application Ser. No. 12/134,682, filed on Jun. 6, 2008, the disclosure of which is incorporated fully by reference.

### FIELD OF THE INVENTION

The present invention relates to semiconductor wafers and semiconductor devices, and more particularly, to a method of making semiconductor wafers and semiconductor devices.

### BACKGROUND OF THE INVENTION

The fabrication of semiconductor wafers, which are then used for the fabrication of semiconductor devices, is a well developed area of technology. Many different semiconductor wafer fabrication methods exist, and there are also many known methods of making semiconductor devices from prefabricated wafers. Semiconductor devices are now ubiquitous in modern technological devices and apparatus.

While many wafers and semiconductor devices are built on a silicon substrate, or similar material, certain devices are preferably built on a sapphire substrate, such as vertical gallium-nitride (GaN)-based light emitting diode (LED). In some known processes, the sapphire substrate is removed using a laser lift off (LLO) process, exposing the various n-type layers for subsequent etching and removal such that an n-type electrode may contact the lightly doped n-type GaN layer.

However, the known methods of manufacturing vertical GaN-based LED, and other semiconductor devices, have limitations in that the LLO process can be inadequate, damaging, and inefficient for manufacturing reliable, efficient LED. Also, due to the similar etching selectively of the various GaN layers, it can be difficult to differentiate the interface between the different layers. Accordingly, there is a need for a method of making semiconductor devices that solves the shortcomings of known methods.

### SUMMARY OF THE INVENTION

According to one embodiment of the present invention, a semiconductor wafer is disclosed. The semiconductor includes a substrate; a plurality of ceramic polishing stops on the substrate; one or more buffer layers grown on the substrate; and one or more epitaxial layers on the one or more buffer layers.

According to another embodiment of the present invention, a light emitting diode is disclosed. The light emitting diode includes a substrate; a plurality of semiconductor layers grown on the substrate, wherein the plurality of semiconductor layers includes an active layer and a plurality of ceramic polishing stops; and one or more electrodes applied to one or more of the plurality of semiconductor layers.

According to another embodiment of the present invention, a method of making a semiconductor device is disclosed. The method of making a semiconductor device includes providing a substrate; forming a plurality of ceramic polishing stops on the substrate; growing one or more buffer layers on the substrate; and growing one or more epitaxial layers on the one or more buffer layers.

Still other embodiments of the present invention will become readily apparent to those skilled in the art from the following detailed description, wherein embodiments of the invention are described by way of illustration. As will be realized, the invention is capable of other and different embodiments and its several details are capable of modifications in various respects, all without departing from the spirit and the scope of the present invention.

### BRIEF DESCRIPTION OF THE DRAWINGS

FIG. 1 is a cross-sectional view of a semiconductor wafer showing the formation of polishing stops, according to an embodiment of the present invention.

FIG. 2 is a cross-sectional view of a semiconductor wafer showing the growth of epitaxial layers, according to an embodiment of the present invention.

FIG. 3 is a cross-sectional view of a semiconductor wafer showing the formation of polishing stops on an epitaxial layer, according to an embodiment of the present invention.

FIG. 4 is a cross-sectional view of a semiconductor wafer showing the formation of photonic structures in an epitaxial layer, according to an embodiment of the present invention.

FIG. 5 is a cross-sectional view of a semiconductor wafer showing the formation of polishing stops combined with an etching stop layer, according to an embodiment of the present invention.

FIG. 6 is a cross-sectional view of a semiconductor wafer showing the formation of polishing stop layers, according to an embodiment of the present invention.

FIG. 7 is a cross-sectional view of a semiconductor device showing the formation of polishing stops, according to an embodiment of the present invention.

FIG. 8 is a cross-sectional view of a semiconductor device showing the formation of a built-in contact, according to an embodiment of the present invention.

FIG. 9 is a cross-sectional view of a semiconductor device showing the formation of a new substrate, according to an embodiment of the present invention.

FIG. 10 is a cross-sectional view of a semiconductor device showing patterned plating, according to an embodiment of the present invention.

FIG. 11 is a cross-sectional view of a semiconductor device showing substrate removal, according to an embodiment of the present invention.

FIG. 12 is a cross-sectional view of a semiconductor device showing example semiconductor device surface variations, according to an embodiment of the present invention.

FIG. 13 is a cross-sectional view of a semiconductor device showing the formation of a built-in contact, according to an embodiment of the present invention.

FIG. 14A is a cross-sectional view of a semiconductor wafer showing the formation of polishing stops, according to an embodiment of the present invention.

FIG. 14B is a cross-sectional view of a semiconductor wafer showing the formation of polishing stops, according to another embodiment of the present invention.

FIG. 14C is a cross-sectional view of a semiconductor wafer showing the formation of polishing stops, according to another embodiment of the present invention.

FIG. 15 is a cross-sectional view of a semiconductor wafer showing the growth of epitaxial layers, according to an embodiment of the present invention.

FIG. 16 is a cross-sectional view of a semiconductor wafer showing the formation of polishing stops on an epitaxial layer, according to an embodiment of the present invention.

FIG. 17 is a cross-sectional view of a semiconductor wafer showing the formation of polishing stops combined with an etching stop layer, according to an embodiment of the present invention.

FIG. 18 is a cross-sectional view of a semiconductor device showing the formation of polishing stops, according to an embodiment of the present invention.

FIG. 19 is a cross-sectional view of a semiconductor device showing the formation of a new substrate, according to an embodiment of the present invention.

FIG. 20 is a cross-sectional view of a semiconductor device showing substrate removal, according to an embodiment of the present invention.

FIG. 21 is a cross-sectional view of a semiconductor device showing example semiconductor device surface variations, according to an embodiment of the present invention.

FIG. 22A is a vertical LED structure, according to an embodiment of the present invention.

FIG. 22B is a vertical LED structure, according to an embodiment of the present invention.

FIG. 22C is a vertical LED structure, according to an embodiment of the present invention.

FIG. 23 is a flip chip LED structure, according to another embodiment of the present invention.

### DETAILED DESCRIPTION

In the following description, reference is made to the accompanying drawings where, by way of illustration, specific embodiments of the invention are shown. It is to be understood that other embodiments may be used as structural and other changes may be made without departing from the scope of the present invention. Also, the various embodiments and aspects from each of the various embodiments may be used in any suitable combinations. Accordingly, the drawings and detailed description are to be regarded as illustrative in nature and not as restrictive.

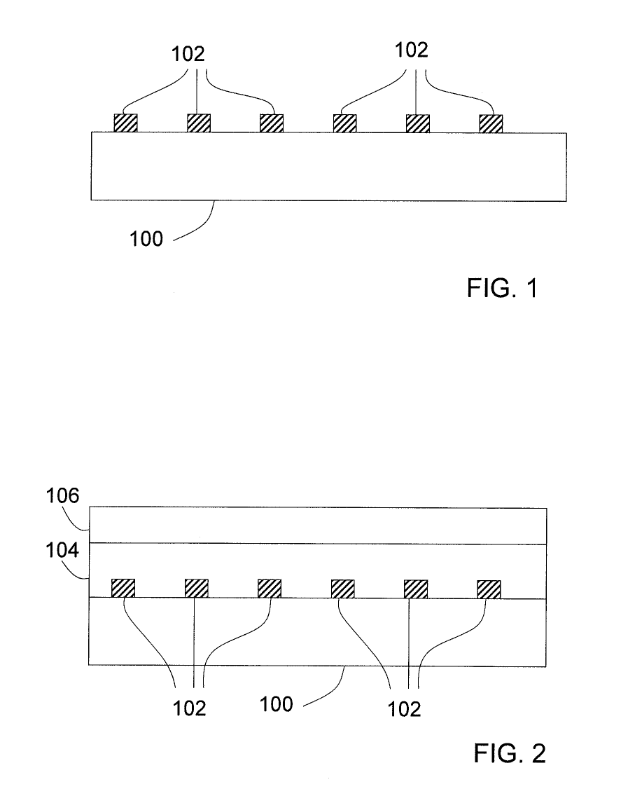

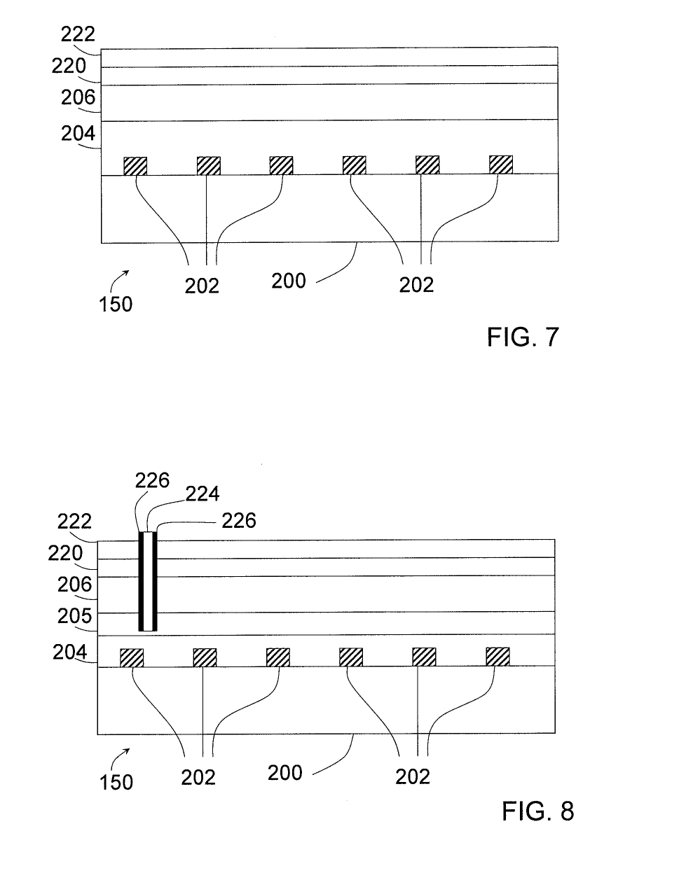

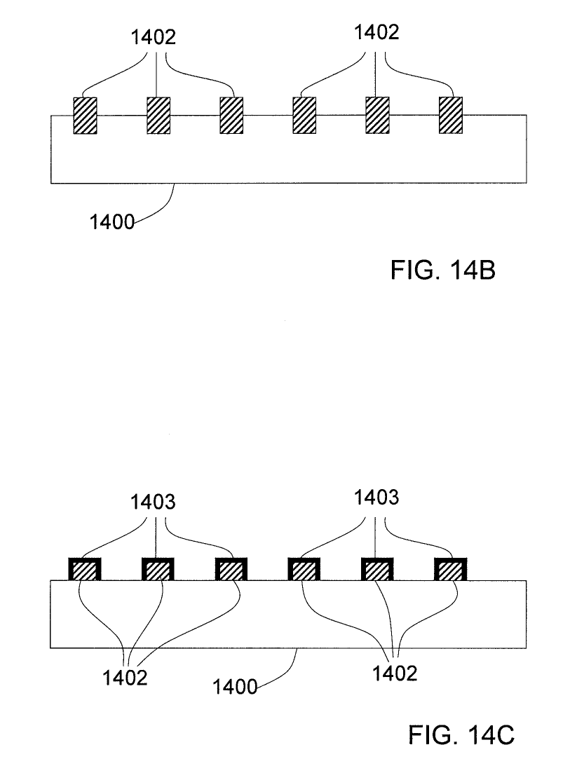

Generally, the present invention is directed to semiconductor wafers, semiconductor devices, and methods of making semiconductor wafers and devices. Embodiments of the present invention are suitable for use with substrate substitution, wherein removal of the substrate is facilitated by the composition of the semiconductor wafer or semiconductor device and a new, second substrate is applied. FIGS. 1 to 6 are directed generally to methods of making a semiconductor wafer. FIGS. 7 to 13 are directly generally to methods of making semiconductor devices using the semiconductor wafer described with reference to FIGS. 1 to 6. FIGS. 14A to 22C are directed generally to a second embodiment of the semiconductor wafer and a method of making a semiconductor wafer and semiconductor devices. The second embodiment includes a light enhancement layer that may be used, for example, for dislocation reduction, reducing stacking fault during epitaxial lateral overgrowth, and achieving improved internal quantum efficiency. In embodiments of the present invention, the polishing stops include ceramic materials and the polishing stops may function as the light enhancement layer.

The embodiments shown and described with reference to the figures may be used in the fabrication of LED, and specifically vertical GaN-based LED. However, it will be appreciated that the described methods are not limited to any specific engineering applications and any suitable semiconductor devices may be made according to embodiments of the present invention such as, for example, LED, laser diodes, transistors and other power devices, growth and fabrication of free-standing semiconductor materials, and other suitable applications.

In the fabrication of GaN-based LED, specifically, the removal of the base sapphire substrate and replacement of it with a new substrate has advantages, such as improved thermal management, enhanced light extraction through surface texturing on the newly exposed surface, and more uniformity in current distribution. According to embodiments of the present invention, removal of the sapphire substrate is generally performed by a mechanical thinning method, such as grinding, lapping, polishing, and/or chemical mechanical polishing, used in the fabrication of semiconductor devices, such as the manufacture of LED, using polishing stops. According to embodiments of the present invention, polishing stops are provided during the wafer growth or wafer fabrication stage, thereby providing higher yield and improved device performance.

Throughout the descriptions, use of the prefix “u-” stands for undoped or lightly doped, “p-” stands for p-type or positive, and “n-” stands for n-type or negative.

Referring now to the figures, FIG. 1 is a cross-sectional view of a semiconductor wafer showing the formation of polishing stops, according to an embodiment of the present invention. A substrate 100 is provided. Polishing stops 102 are formed on the substrate. The polishing stops may be formed using any suitable method. According to one example method, referred to as a subtraction method, a layer of hard material is applied to the entire surface of the substrate 100. A pattern is then formed in the layer of hard material, removing the undesired parts of the layer of hard material and leaving only the desired polishing stops 102. According to another example method, referred to as the addition method, a mask pattern is created across the surface of the substrate 100, leaving holes or trenches, or other desired shapes of openings. Then, a hard material is deposited across the substrate 100 and into the openings. The mask pattern is then removed leaving the polishing stops 102 along the surface of the substrate 100. The application and removal of masks may be done using known photoresist processes. According to one embodiment, the polishing stops 102 are formed on the substrate 100. However, according to another embodiment, the polishing stops 102 are formed on other layers of the semiconductor wafer.

One example substrate is formed of sapphire, which is well suited for vertical LED fabrication processes. Embodiments of the present invention may be especially suited for used with type III-V, non-silicon materials. In type III-V material, the epitaxial growth process may be important in the construction and operation of devices later formed on the semiconductor wafer. However, applications of the present invention should not necessarily be limited to these materials, and any other suitable substrate materials may be used in accordance with embodiments of the present invention.

The hard material is any suitable hard material. In one example embodiment, the hard material is the hardest of all materials being used in the wafer or device. The hard material may be diamond film or diamond like carbon (DLC) film. Other suitable hard material for use as polishing stops 102 may be, for example, diamond, diamond like carbon (DLC), titanium nitride (TiNx), titanium tungsten (TiWx) alloy, transition metal nitride, or other suitable materials. The size of the polishing stops can be any width and height required for the particular application of the wafer being fabricated. Also, the term “hard” as used to describe the polishing stops 102 is not meant to be limited to the examples given or to any specific levels of hardness or softness but may be any type of material suitable for accomplishing the described method.

FIG. 2 is a cross-sectional view of a semiconductor wafer showing the growth of epitaxial layers, according to an embodiment of the present invention. After the hard material is applied to the substrate 100 in the form of polishing stops 102, one or more epitaxial layers 104, 106 are grown on the substrate 100. In the illustrated embodiment shown in FIG. 2, a buffer layer 104, such as a u-GaN layer, is grown on the substrate 100. While only one layer epitaxial 106 is shown being grown on the buffer layer 104, this layer is intended to represent any number of layers of any suitable semiconductor materials that can be grown according to the particular application requirements. Similarly, while only one buffer layer 104 is shown, this layer is intended to represent one or more buffer layers, as required. One example configuration for the epitaxial growth, which may be used for the production of GaN LED, includes an undoped, or lightly doped, u-GaN layer grown on the sapphire substrate 100, followed by one or more highly doped n-type GaN (n-GaN) layers, an active layer having a multiple quantum well (MQW) structure, and a p-type GaN (p-GaN) layer. However, the illustrated examples are not intended to limit the present invention to any particular number or ordering of different epitaxial layers.

Generally, it can be difficult to know the thickness of the u-Gan layer, and also difficult to know with certainty the interface, or junction, between u-GaN and the remaining layers, such as the n-type layers. Accordingly, the ability to do this in known fabrication methods has proven difficult, costly, and/or not possible. Therefore, embodiments of the present invention also provide for the removal of the u-GaN layer with certainty, knowing with the required degree of certainty where the sapphire substrate removal should be stopped.

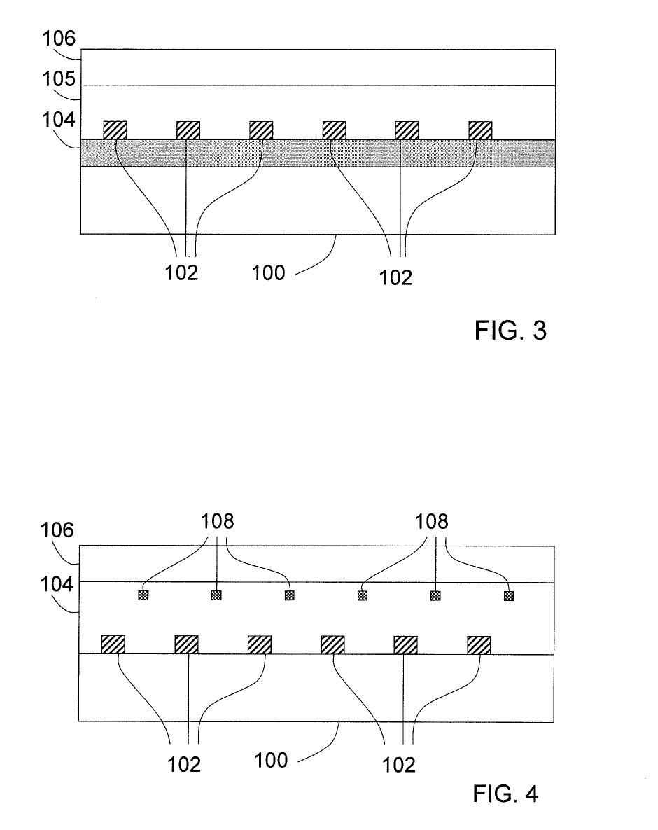

FIG. 3 is a cross-sectional view of a semiconductor wafer showing the formation of polishing stops on an epitaxial layer, according to an embodiment of the present invention. In the illustrated embodiment shown in FIG. 3, one or more first buffer layers 104 is grown on the substrate 100. Polishing stops 102 are then formed on one of the first buffer layers 104. Another one or more buffer layers 105 may be grown on the polishing stops 102. Then one or more epitaxial layers 106 may be grown on the second buffer layers 105. As similarly described with reference to FIG. 2, while only one layer 106 is shown being grown on the second buffer layer 105, this layer is intended to represent any number of layers of any suitable semiconductor materials that can be grown according to the particular application requirements.

FIG. 4 is a cross-sectional view of a semiconductor wafer showing the formation of photonic structures in an epitaxial layer, according to an embodiment of the present invention. The example embodiment illustrated in FIG. 4 is similar to FIG. 2, having a substrate 100, polishing stops 102 applied to the substrate 100, one or more buffer layers 104, and one or more epitaxial layers 106 grown on the one or more buffer layers 104. Light altering materials 108 are added to the one or more buffer layers 104. The light altering materials 108 may be light scattering elements for enhanced light extraction, in the case of LED fabrication. For example, photonic crystal structures may be added by etching or by the addition of materials to the layer, such as silicon dioxide (SiO₂) or silicon nitride (SiN). The photonic structures may also be a vacuum or include the absence of materials at predetermined locations within the material layers.

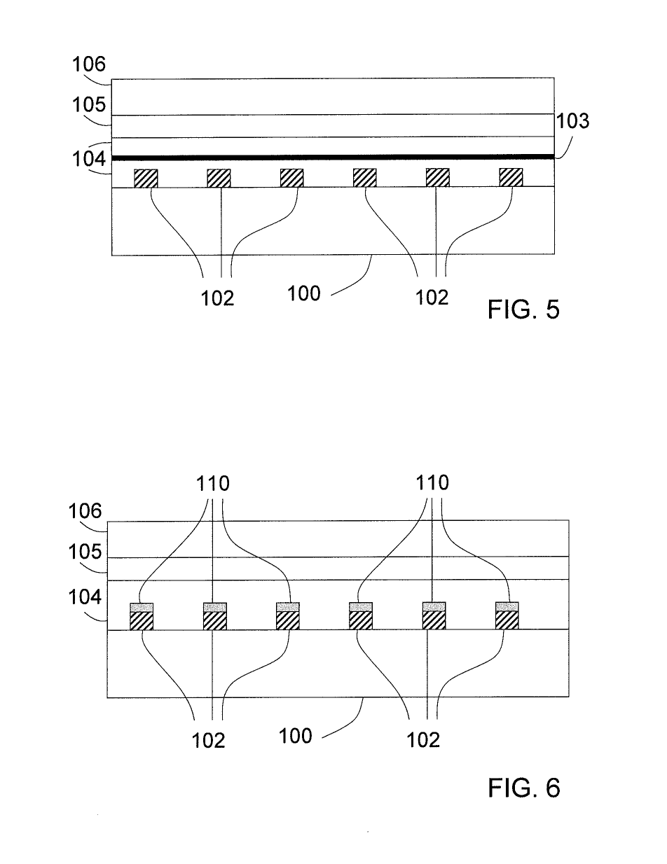

FIG. 5 is a cross-sectional view of a semiconductor wafer showing the formation of polishing stops combined with an etching stop layer, according to an embodiment of the present invention. The example embodiment illustrated in FIG. 5 is similar to FIG. 2, having a substrate 100, polishing stops 102 applied to the substrate 100, one or more buffer layers 104, 105, and one or more epitaxial layers 106 grown on the one or more buffer layers 104, 105. Additionally, an etching stop layer 103 is grown in or between the one or more buffer layers 104. The etching stop layer 103 may be advantageous during later etching processes. In one embodiment, highly selective wet etching will be used, however dry etching and other suitable etching methods as known by those of skill in the field may also be used. One or more stop layers may be used for subsequent processes after the removal of the substrate 100. For example, etching processes may be terminated at the stop layer 103. The stop layer may also serve as a leakage reduction layer, such as in the later use of the wafer for manufacturing transistors and the like.

According to one embodiment, the stop layer 103 is an AlInGaN layer that has the property of AlₓIn_{y}Ga_{(1-x-y)}N. In one embodiment, x is less than or equal to approximately 0.35. In another embodiment, x is less than or equal to approximately 0.4. In another embodiment, x may be in a range of 0.2 to 0.5. In one embodiment, y is less than or equal to approximately 0.1. In another embodiment, y is less than or equal to approximately 0.2 or within a range of 0.05 to 0.25. However, other suitable values and other ranges for the values of x and y may be used. According to another embodiment, the stop layer 103 may be a highly doped AlGaN layer having the property AlₓGa₍₁₋ₓ₎N layer. One possible thickness of the AlGaN layer may be less than 0.2 μm. In another embodiment, thickness of the AlGaN layer may equal to approximately 0.2 μm. In one embodiment, the layer thickness should be thin enough for n-doping into the AlN layer. If a thicker AlₓGa₍₁₋ₓ₎N layer is used as the stop layer, then the Al mole fraction should be less than approximately 0.35 in order to make for more easier doping of Si into the AlGaN layer.

The stop layer provides for high etching selectivity. One method of high etching selectivity uses photo-electrochemical (PEC) wet etching, which is a high bandgap-dependent etching selectivity. PEC etching is the photo-generation of electron hole pairs, which enhances the oxidation and reduction reaction in an electrochemical reaction. The stop layer 103 may also comprise a AlN/GaN super lattice structure, according to an embodiment of the present invention. The super lattice stop layer comprises a GaN layer and an AlN layer, which together form an AlN/GaN super lattice (˜30 Å/30 Å stop layer. The super lattice structure is formed by adjacent layers of AlN and GaN. The super lattice structure may comprise any desired number of pairs of AlN and GaN.

FIG. 6 is a cross-sectional view of a semiconductor wafer showing the formation of polishing stop layers, according to an embodiment of the present invention. The example embodiment illustrated in FIG. 6 is similar to FIG. 2, having a substrate 100, polishing stops 102 applied to the substrate 100, one or more buffer layers 104, 105, and one or more epitaxial layers 106 grown on the one or more buffer layers 104, 105. Additionally, a polishing stop layer 110 is added to each of the polishing stops 102. The polishing stop layer 110 may reduce stress or lattice mismatch between the polishing stop 102 and the buffer layer 104. The polishing stop layer 110 may also be used for dislocation reduction by epitaxial lateral overgrowth.

According to one embodiment, each of the polishing stops 102 is made from first material, and each of the polishing stop layers is made from a second material, the advantage being provided by the difference between the two materials. According to another embodiment, the polishing stop layer may fully surround and cover the polishing stop, such that no part of the polishing stop contacts the surrounding layer that is adjacent to the polishing stops 102.

Referring now to FIGS. 7 to 13, the semiconductor wafer described with reference to FIGS. 1 to 6 may be further used in the making of semiconductor devices.

FIG. 7 is a cross-sectional view of a semiconductor device 150 showing the formation of polishing stops, according to an embodiment of the present invention. The example embodiment illustrated in FIG. 7 includes the components shown in FIG. 2 in addition to other layers. The semiconductor device 150 includes a substrate 200, polishing stops 202 applied to the substrate 200, one or more buffer layers 204 grown on the substrate 200, and one or more epitaxial layers 206 grown on the one or more buffer layers 204. Additionally, during the fabrication of semiconductor devices, additional layers maybe added to the one or more epitaxial layers 206 using a build-up or lamination process or any other suitable fabrication processes. In the illustrated embodiment, the semiconductor device 150 includes one or more metal layers 220, 222. The one or more metal layers 220, 222 may be any such materials as required by the particular application, such as Ohmic contact, mirror, plating seed layer, bonding materials, buffer layers for stress, or other metal layers.

FIG. 8 is a cross-sectional view of a semiconductor device showing the formation of a built-in contact, according to an embodiment of the present invention. The example embodiment illustrated in FIG. 8 is similar to that shown in FIG. 7, the semiconductor device 150 having a substrate 200, polishing stops 202 applied to the substrate 100, one or more buffer layers 204 grown on the substrate, one or more conductive layers 205 grown on the one or more buffer layers 204, one or more epitaxial layers 206 grown on the one or more conductive layers 205, and one or more metal layers 220, 222 added to the one or more epitaxial layers 206. The semiconductor device 150 further includes a built-in n-type contact 224 that extends into the one or more conductive layers 205. The n-type contact 224 may be surrounded by insulating material 226 to prevent or reduce contact with other semiconductor device layers.

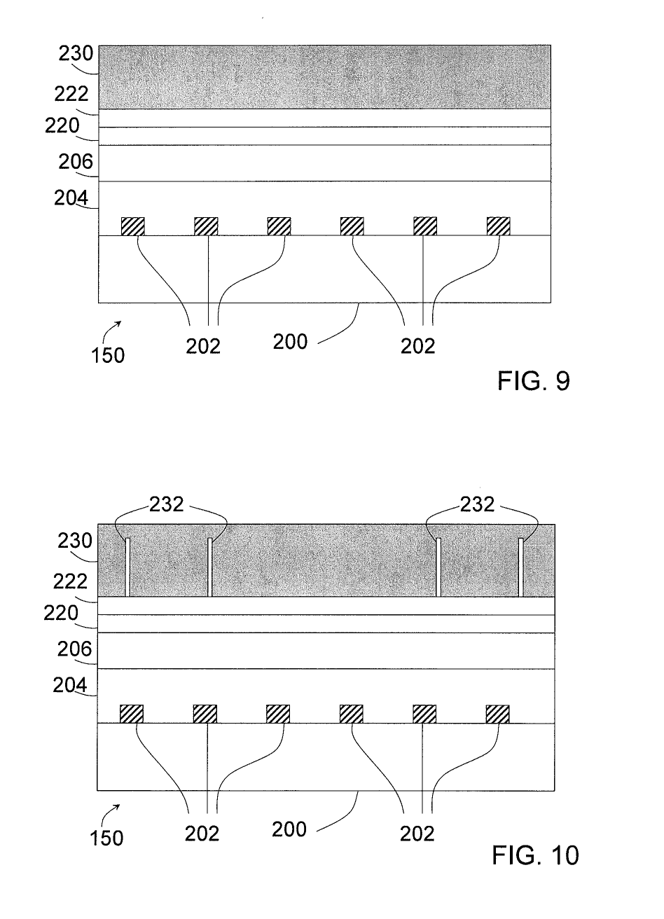

FIG. 9 is a cross-sectional view of a semiconductor device showing the formation of a new substrate, according to an embodiment of the present invention. The example embodiment illustrated in FIG. 9 is similar to that shown in FIG. 7, the semiconductor device 150 having a substrate 200, polishing stops 202 applied to the substrate 200, one or more buffer layers 204 grown on the substrate 200, one or more epitaxial layers 206 grown on the one or more buffer layers 204, and one or more metal layers 220, 222 added to the one or more epitaxial layers 206. The semiconductor device 150 further includes a second substrate 230 bonded or plated to the one or more metal layers 220, 222. For example, the second substrate may be formed from any suitable material, such as, for example, copper or other materials suitable as a semiconductor device substrate.

FIG. 10 is a cross-sectional view of a semiconductor device showing patterned plating, according to an embodiment of the present invention. The example embodiment illustrated in FIG. 10 is similar to that shown in FIG. 9, the semiconductor device 150 having a substrate 200, polishing stops 202 applied to the substrate 200, one or more buffer layers 204 grown on the substrate 200, one or more epitaxial layers 206 grown on the one or more buffer layers 204, one or more metal layers 220, 222 added to the one or more epitaxial layers 206, and a second substrate 230 bonded or plated to the one or more metal layers 220, 222. In the illustrated embodiment, patterned plating 232 of the second substrate 230 may facilitate dicing and stress release when separating the semiconductor device 150 into individual, separate components. In one embodiment, the patterned plating 232 is formed using a photoresist process.

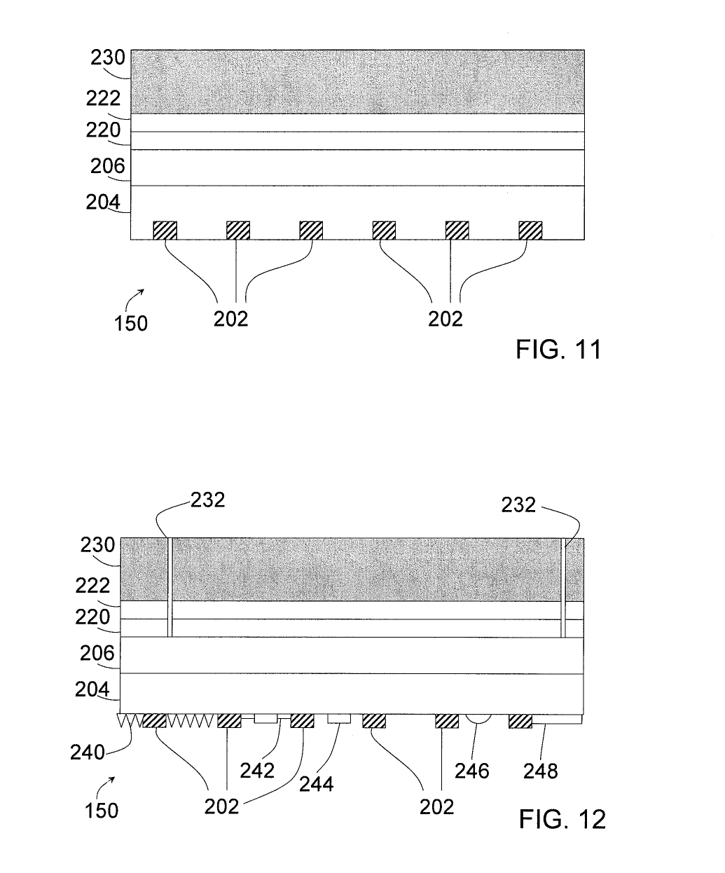

FIG. 11 is a cross-sectional view of a semiconductor device showing substrate removal, according to an embodiment of the present invention. The example embodiment illustrated in FIG. 11 is similar to that shown in FIG. 9, the semiconductor device 150 having polishing stops 202 formed in the one or more buffer layers 204 that were applied to the substrate 200 (FIGS. 9 and 10), one or more epitaxial layers 206 grown on the one or more buffer layers 204, one or more metal layers 220, 222 added to the one or more epitaxial layers 206, and the second substrate 230 bonded or plated to the one or more metal layers 220, 222. In the illustrated embodiment of FIG. 11, when compared to FIGS. 9 and 10, the substrate 200 has been removed. In one embodiment, the substrate 200 is removed by a mechanical thinning process, which generally may include grinding, lapping, polishing or chemical mechanical polishing of the surface as part of the process. Other removal methods may be used. However, using a mechanical thinning method in combination with embodiments of the present invention provides added advantages of speed and accuracy. As illustrated in FIG. 11, the removal by the mechanical thinning process stops at the ends of the polishing stops 202. As the polishing stops 202 are formed from a hard material, mechanical thinning can be stopped with certainty and precision at the location of the polishing stops, leaving the remaining layers. Also, through the use of polishing stops 202 the flatness of the remaining surface can be controlled within required limits.

FIG. 12 is a cross-sectional view of a semiconductor device showing example semiconductor device surface variations, according to an embodiment of the present invention. The example embodiment illustrated in FIG. 12 is similar to that shown in FIG. 11, the semiconductor device 150 having polishing stops 202 formed in the one or more buffer layers 204 that were applied the substrate 200 (FIGS. 9 and 10), one or more epitaxial layers 206 grown on the one or more buffer layers 204, one or more metal layers 220, 222 added to the one or more epitaxial layers 206, and the second substrate 230 bonded or plated to the one or more metal layers 220, 222. At least a portion of the buffer layer 204 has been removed during an etching process, thereby exposing at least part of the polishing stops 202. A plurality of different LED features have been shown on the semiconductor device 150 for illustration purposes. For example, shown in FIG. 12 are surface texturing 240, passivation 242, and Ohmic contact or bonding pad 244, a microlens 246, and a transparent contact layer 248. Additionally, patterned plating 232 is formed in the second substrate 230 and the one or more metal layers 220, 222 to facilitate dicing and stress release when separating the semiconductor device 150 into individual, separate components.

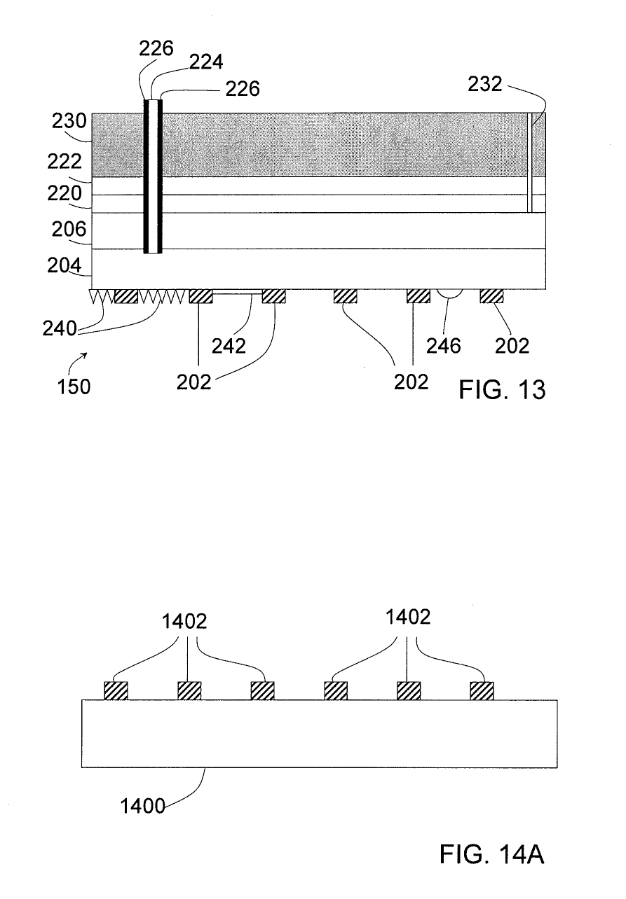

FIG. 13 is a cross-sectional view of a semiconductor device showing the formation of a built-in contact, according to an embodiment of the present invention. The example embodiment illustrated in FIG. 13 is similar to that shown in FIG. 12, further including a built-in n-type contact 224 that extends into the one or more conductive layers 205. The n-type contact 224 may be surrounded by insulating material 226 to prevent or reduce contact with other semiconductor layers.

Referring now to FIGS. 14A to 21, a semiconductor wafer and a method of making a semiconductor are shown and illustrated. Unless otherwise described, the embodiments of the semiconductor wafer and method of making the semiconductor wafer shown and illustrated with reference to FIG. 14A to 21 are similar to that described with reference to FIGS. 1 to 13.

FIG. 14A is a cross-sectional view of a semiconductor wafer showing the formation of polishing stops, according to an embodiment of the present invention. A substrate 1400 is provided. Polishing stops 1402 are formed on the substrate. The polishing stops 1402 may be formed using any suitable method. According to one example method, referred to as a subtraction method, a layer of hard material is applied to the entire surface of the substrate 1400. A pattern is then formed in the layer of hard material, removing the undesired parts of the layer of hard material and leaving only the desired polishing stops 1402. For example, reactive-ion etching (RIE) may be used to form the pattern of hard material. Polishing stops may also be formed by chemical vapor deposition or physical vapor deposition. According to another example method, referred to as the addition method, a mask pattern is created across the surface of the substrate 100, leaving holes or trenches, or other desired shapes of openings. Then, the hard material is deposited across or grown on the substrate 1400 in the form of nanostructures. In another embodiment, using a recession method, holes may be made completely through the hard material and the holes filled with a semiconductor material. Accordingly, the semiconductor material may be contacted by other semiconductor materials or components located on both sides of the hard material. According to one embodiment, the polishing stops 1402 are formed on the substrate 1400. However, according to another embodiment, the polishing stops 1402 are formed on other layers of the semiconductor wafer. According to one embodiment, the polishing stops may be formed on a patterned substrate, as shown and described in FIG. 14B.

One example substrate is formed of sapphire, which is well suited for vertical LED fabrication processes. Embodiments of the present invention may be especially suited for used with type III-V, non-silicon materials. In type III-V material, the epitaxial growth process may be important in the construction and operation of devices later formed on the semiconductor wafer. However, applications of the present invention should not necessarily be limited to these materials, and any other suitable substrate materials may be used in accordance with embodiments of the present invention.

The hard material used with reference to FIGS. 14A to 22C includes ceramic material or ceramic-based material. In one embodiment, the ceramic is boron nitride or boron nitride-based material. However, according to another embodiment, other ceramic materials may be used, such as TiSiN or TiAlN. According to one embodiment, transition metal nitride material may be used. According to one embodiment, the friction coefficient of the hard material is lower than that of the original substrate and the semiconductor layers on the substrate. Any suitable forms of boron nitride may be used such as, for example, cubic boron nitride, ternary boron nitride, carbonized boron nitride (CBN), germanium ternary boron nitride (GeBN), boron fluoronitride (BFN), boron oxynitride (BNO), boron nitride fibers, boron nitride nanomesh, boron nitride nanostructures including, for example, nanotube, nanowire, nanocone, and nanohone, or composites containing boron nitride. In one embodiment, the ceramic material is transparent to light emitted by an active layer formed in the semiconductor wafers according to embodiments of the present invention, the ceramic material having a refractive index lower than the refractive index of the semiconductor layer adjacent to the ceramic material. Accordingly, using a hard material with a refractive index lower than the active region may reduces the amount of reflected light.

According to one embodiment, the ceramic material is grown in a high pressure environment, or a high temperature environment, or an environment that is both high pressure and high temperature. Forming the ceramic material, such as nanotubes, may be performed using: (a) arc-discharge techniques, arcing HfB₂/Ta—BN electrodes (boron containing) in an inert atmosphere or N₂ or NH₃; (b) laser ablation of boron nitride (BN) powder mixed with nano-sized Ni and Co powder in an inert atmosphere at a high temperature, such as 1200° C.; (c) substitution reactions, such as CNT, with BN nanotubes formed using a CNT template B₂O₃ powders under N₂ at high temperature, such as 1500° C.; (d) chemical vapor deposition, precursor, such as B₄N₃O₂H, B₃N₃H₆)+catalyst, such as NiB or Ni₂B powder, at a high temperature >1000° C.; or (e) ball milling, using elemental B in NH₃ gas followed by thermal annealing at a high temperature, such as 1000-1200° C. under N₂ or Ar.

The hard material polishing stops may be patterned or grown in any suitable pattern or shape. For example, each polishing stop may be have a round, rectangular, triangular cross-section or be conical. The polishing stops may be distributed on the semiconductor wafer in any patterns, such as a grid of any suitable grid pattern. The size, width, and spacing of a pattern of polishing stops may be optimized according to the particular application. According to one embodiment, the polishing stops could be comprised of a stack of multiple layers, at least one layer of the stack of multiple layers includes boron nitride-based material.

According to one example embodiment, etching of the hard material, such as boron nitride nanocone or nanopillar, is done by dry etching, such as assisted RIE under hydrogen gas. Such etching method would involve both physical etching by energetic ion impact and chemical etching by reactive hydrogen atoms/ions. The reactions involved in the chemical etching may be: N(surface)+xH(g)→NHx(g); B(surface)+xH(g)→BHx(g). A metal etching mask, such as Ti, Al, or Au, is used to induce preferential RIE. According to one embodiment, the hard material patterning can be achieved by deposition on the patterned mask, and then liftoff of the mask.

However, with suitable embedded material, such as boron nitride based materials on the substrate, it may not only improves the dislocation density and stacking fault in epitaxial layer to achieve better internal quantum efficiency, but the embedded material may also act as a polishing stop in the substrate removal process given the high level of hardness of the embedded material. Moreover, with suitable tuning of boron nitride based material, its can also help to scatter and/or enhance the light extraction with its in-between refractive index (n˜1.7-2.1) when comparing with GaN (n˜2.5) and air (n˜1).

Considering micropillar structures in the n-GaN layer, the light output power at 350 mA of the micropillar InGaN/Cu LED sample can be improved by 39% as compared with that of the conventional InGaN/Cu LED. This improvement was caused because the photon escaping probability, caused by scattering the emission light at the micropillar surface, was increased. By further optimizing the micropillar spacing, better light extraction efficiency may be achieved.

FIG. 14B is a cross-sectional view of a semiconductor wafer showing the formation of polishing stops, according to another embodiment of the present invention. In the illustrated embodiment of FIG. 14B, the polishing stops 1402 are grown into, or below the surface of, the substrate 1400. During the growth process, holes or recesses are made into the substrate 1400, and the material used to form the polishing stops 1402 is at least partially located in the holes or recesses.

FIG. 14C is a cross-sectional view of a semiconductor wafer showing the formation of polishing stops, according to another embodiment of the present invention. According to one embodiment, each of the polishing stops 1402 is made from first material, and each of the polishing stops 1402 includes a conformal layer or covering layer 1403 made from a second material. An advantage may be provided by the difference between the two materials. In the embodiment illustrated in FIG. 14C, the polishing stop layer fully surrounds and covers the polishing stop, such that no part of the polishing stop contacts the surrounding layer that is adjacent to the polishing stops 1402. However, the conformal layer may also cover a part of the polishing stops 1402, such as the top of the polishing stops 1402. For example, the conformal layer 1403 may include or be comprised of SiO₂ or SiNₓ or multiple layers of one or more of these materials. In another embodiment, the conformal layer 1403 provides a similar function as the polishing stop layers 110 illustrated and described with reference to FIG. 6.

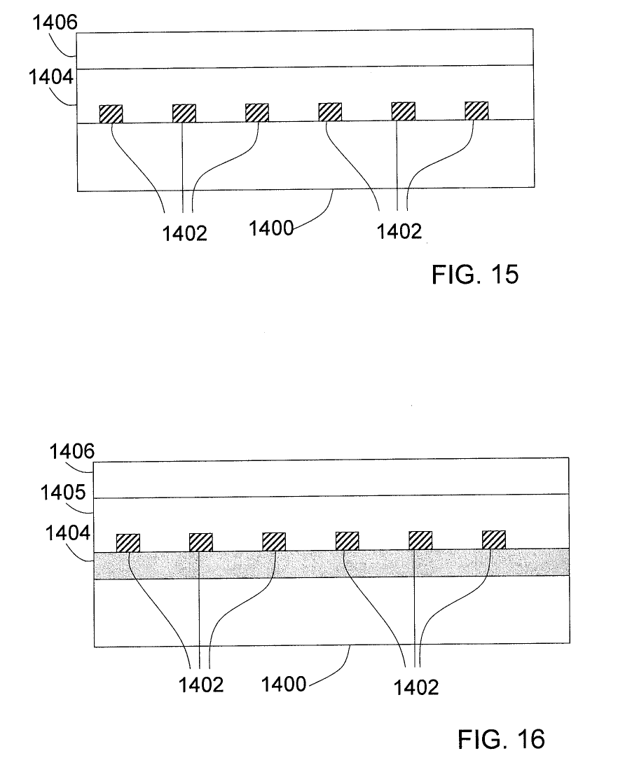

FIG. 15 is a cross-sectional view of a semiconductor wafer showing the growth of epitaxial layers, according to an embodiment of the present invention. After the hard material is applied to the substrate 1400 in the form of polishing stops, one or more epitaxial layers 1404, 1406 are grown on the substrate 1400. In the illustrated embodiment shown in FIG. 15, a buffer layer 1404, such as a u-GaN layer or GaN cladding layer, is grown on the substrate 1400. While only one layer epitaxial 1406 is shown being grown on the buffer layer 1404, this layer is intended to represent any number of layers of any suitable semiconductor materials that can be grown according to the particular application requirements. One example configuration for the epitaxial growth, which may be used for the production of GaN LED, includes an undoped, or lightly doped, u-GaN layer 1404 grown on the sapphire substrate 1400, followed by one or more highly doped n-type GaN (n-GaN) layers, an active layer having a multiple quantum well (MQW) structure, and a p-type GaN (p-GaN) layer. However, the illustrated examples are not intended to limit the present invention to any particular number or ordering of different epitaxial layers.

FIG. 16 is a cross-sectional view of a semiconductor wafer showing the formation of polishing stops on an epitaxial layer, according to an embodiment of the present invention. In the illustrated embodiment shown in FIG. 16, one or more first buffer layers 1404 is grown on the substrate 1400. Polishing stops 1402 are then formed on one of the first buffer layers 1404. Another one or more buffer layers 1405 may be grown on the polishing stops 1402. Then one or more epitaxial layers 1406 may be grown on the second buffer layers 1405. As similarly described with reference to FIG. 15, while only one layer 1406 is shown being grown on the second buffer layer 1405, this layer 1406 is intended to represent any number of layers of any suitable semiconductor materials that can be grown according to the particular application requirements.

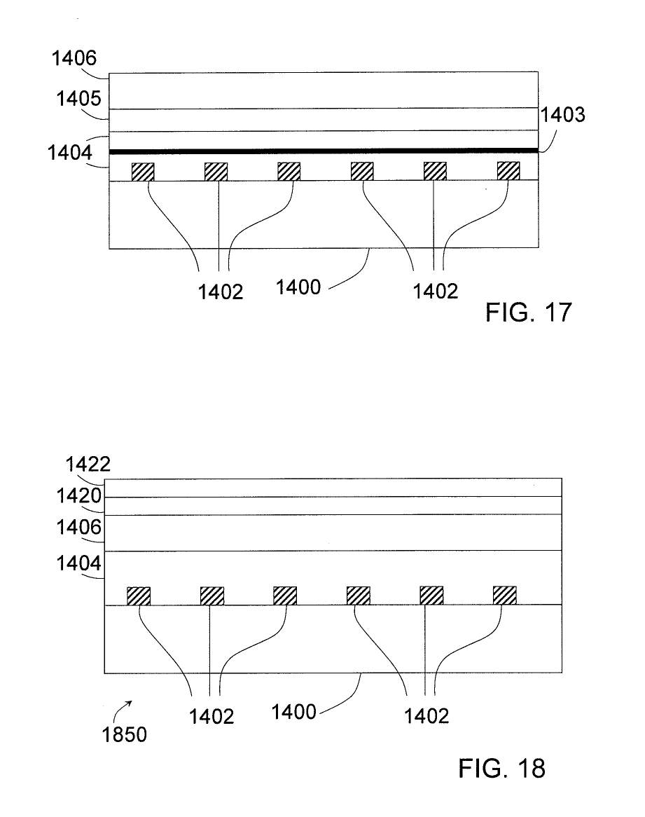

FIG. 17 is a cross-sectional view of a semiconductor wafer showing the formation of polishing stops combined with an etching stop layer 1403, according to an embodiment of the present invention. The example embodiment illustrated in FIG. 17 is similar to FIG. 15, having a substrate 1400, polishing stops 1402 applied to the substrate 1400, one or more buffer layers 1404, 1405, and one or more epitaxial layers 1406 grown on the one or more buffer layers 1404, 1405. Additionally, an etching stop layer 1403 is grown in or between the one or more buffer layers 1404, 1405. The etching stop layer 1403 may be advantageous during later etching processes. In one embodiment, highly selective wet etching will be used, however dry etching and other suitable etching methods as known by those of skill in the field may also be used. One or more stop layers may be used for subsequent processes after the removal of the substrate 1400. For example, etching processes may be terminated at the stop layer 1403. The stop layer may also serve as a leakage reduction layer, such as in the later use of the wafer for manufacturing transistors and the like.

Referring now to FIGS. 18 to 21, the semiconductor wafer described with reference to FIGS. 14 to 17 may be further used in the making of semiconductor devices.

FIG. 18 is a cross-sectional view of a semiconductor device 1850 showing the formation of polishing stops, according to an embodiment of the present invention. The example embodiment illustrated in FIG. 18 includes the components shown in FIG. 2 in addition to other layers. The semiconductor device 1850 includes a substrate 1400, polishing stops 1402 applied to the substrate 1400, one or more buffer layers 1404 grown on the substrate 1400, and one or more epitaxial layers 1406 grown on the one or more buffer layers 1404. Additionally, during the fabrication of semiconductor devices, additional layers maybe added to the one or more epitaxial layers 1406 using a build-up or lamination process or any other suitable fabrication processes. In the illustrated embodiment, the semiconductor device 1850 includes one or more metal layers 1420, 1422. The one or more metal layers 1420, 1422 may be any such materials as required by the particular application, such as Ohmic contact, mirror, plating seed layer, bonding materials, buffer layers for stress, or other metal layers. The one or more metal layers 1420, 1422 may be patterned and do not need to fully contact each other.

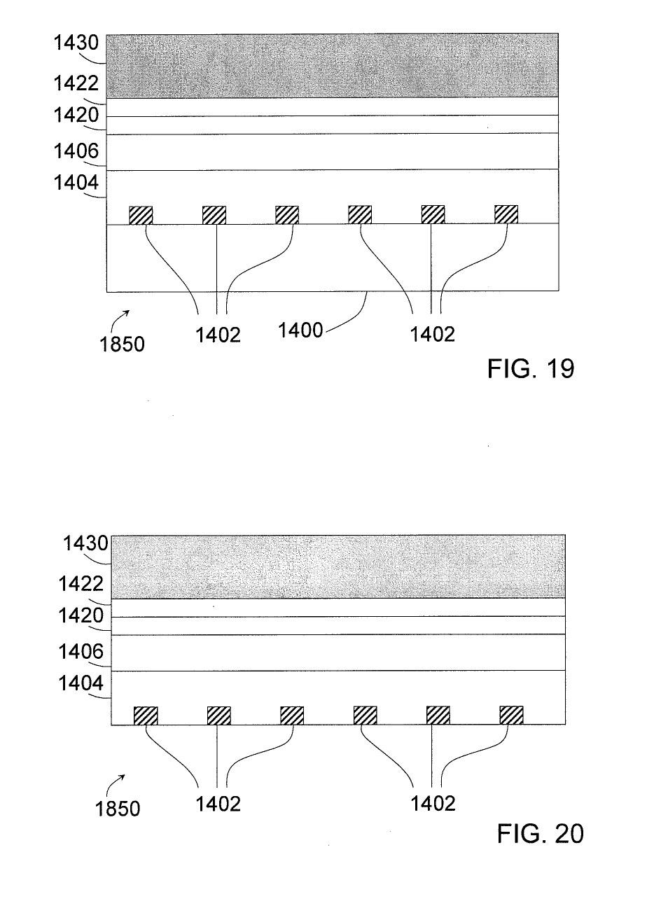

FIG. 19 is a cross-sectional view of a semiconductor device showing the formation of a new substrate, according to an embodiment of the present invention. The example embodiment illustrated in FIG. 19 is similar to that shown in FIG. 18, the semiconductor device 1850 having a substrate 1400, polishing stops 1402 applied to the substrate 1400, one or more buffer layers 1404 grown on the substrate 1400, one or more epitaxial layers 1406 grown on the one or more buffer layers 1404, and one or more metal layers 1420, 1422 added to the one or more epitaxial layers 1406. The semiconductor device 1850 further includes a second substrate 1430 bonded or plated to the one or more metal layers 1420, 1422. For example, the second substrate 1430 may be formed from any suitable material, such as, for example, copper or other materials suitable as a semiconductor device substrate.

FIG. 20 is a cross-sectional view of a semiconductor device showing substrate removal, according to an embodiment of the present invention. The example embodiment illustrated in FIG. 20 is similar to that shown in FIG. 19, the semiconductor device 1850 having polishing stops 1402 formed in the one or more buffer layers 1404 that were applied to the substrate 1400 (FIG. 19), one or more epitaxial layers 1406 grown on the one or more buffer layers 1404, one or more metal layers 1420, 1422 added to the one or more epitaxial layers 1406, and the second substrate 1430 bonded or plated to the one or more metal layers 1420, 1422. In the illustrated embodiment of FIG. 20, when compared to FIG. 9, the substrate 1400 has been removed. In one embodiment, the substrate 1400 is removed by a mechanical thinning process, which generally may include grinding, lapping, polishing or chemical mechanical polishing of the surface as part of the process. Other removal methods may be used. However, using a mechanical thinning method in combination with embodiments of the present invention provides added advantages of speed, accuracy, and throughput. As illustrated in FIG. 20, the removal by the mechanical thinning process stops at the ends of the polishing stops 1402. As the polishing stops 1402 are formed from a hard material, mechanical thinning can be stopped with certainty and precision at the location of the polishing stops, leaving the remaining layers. Also, through the use of polishing stops 1402 the flatness of the remaining surface can be controlled within required limits.

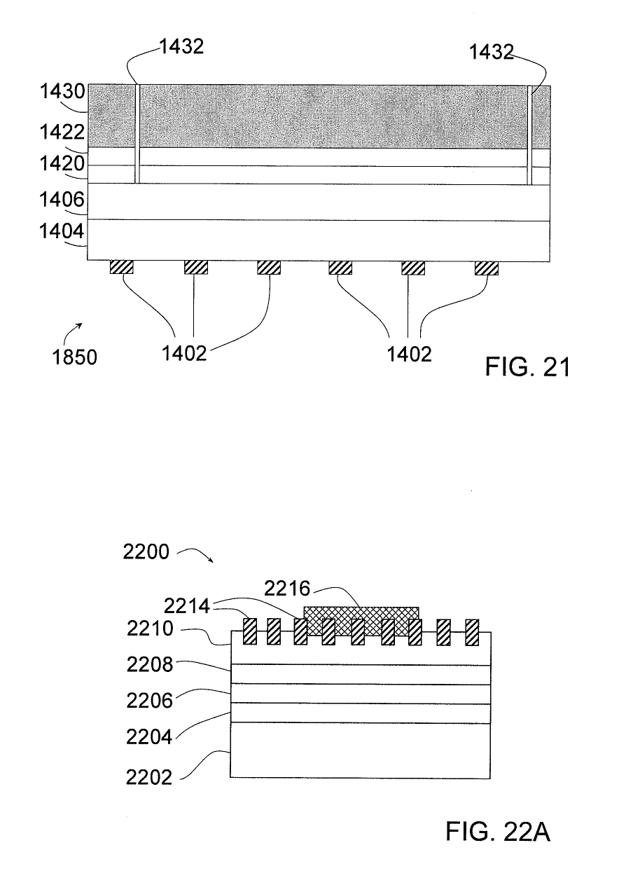

FIG. 21 is a cross-sectional view of a semiconductor device, according to an embodiment of the present invention. The example embodiment illustrated in FIG. 21 is similar to that shown in FIG. 20, the semiconductor device 1850 having polishing stops 1402 formed in the one or more buffer layers 1404 that were applied the substrate 1400 (FIG. 19), one or more epitaxial layers 1406 grown on the one or more buffer layers 1404, one or more metal layers 1420, 1422 added to the one or more epitaxial layers 1406, and the second substrate 1430 bonded or plated to the one or more metal layers 1420, 1422. At least a portion of the buffer layer 1404 has been removed during an etching process, thereby exposing at least part of the polishing stops 1402. Additionally, a non-conductive isolation layer 1432 is formed in the second substrate 1430 and the one or more metal layers 1420, 1422 to facilitate dicing and stress release when separating the semiconductor device 1850 into individual, separate components.

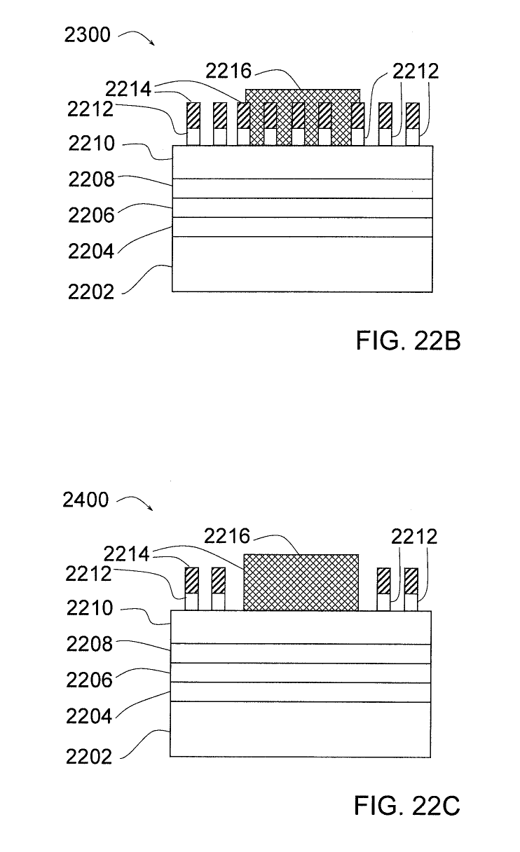

FIG. 22A is a vertical LED structure 2200, according to an example embodiment of the present invention. The vertical LED structure 2200 includes a substitute substrate 2202, a p-metal 2204, a p-GaN layer 2206, a multi-quantum well layer 2208, a n-GaN layer 2210, polishing stops 2214, and an electrode 2216 formed on the n-GaN layer 2210 or on the n-GaN layer 2210 and the polishing stops 2214.

FIG. 22B is a vertical LED structure 2300, according to an embodiment of the present invention. In FIG. 22B, the GaN buffer layer 2212 of the vertical LED structure 2300 has been etched so that the electrode 2216 may directly contact the n-GaN layer 2210. The polishing stops 2214 and the portion of the GaN buffer layer below the polishing stops 2214 remains. Similarly, any suitable layers may be etched according to the requirements of the particular implementation.

FIG. 22C is a vertical LED structure 2400, according to an embodiment of the present invention. The vertical LED structure shown in FIG. 22C is similar to that shown in FIG. 22B. However, in the vertical LED structure 2400 shown in FIG. 22C, the polishing stops 2214 have also been removed in the proximity of the electrode 2216, when compared to FIG. 22B. Accordingly, the polishing stops 2214 may remain on the LED structure or be removed, according to the requirements of the particular application.

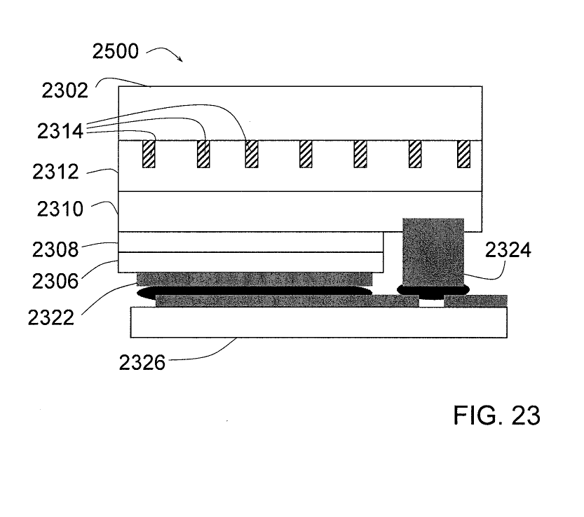

FIG. 23 is a flip chip LED structure, according to another example embodiment of the present invention. The flip chip LED structure 2500 is configured as a flip chip LED including a sapphire substrate 2302, a p-metal layer, 2322, a p-GaN layer 2306, a multi-quantum well layer 2308, a n-GaN layer 2310, a GaN buffer layer 2312, a polishing stop layer 2314, and an n-electrode 2324 formed on the n-GaN layer 2310. The LED structure 2300 is soldered to a submount 2326.

In a conventional semiconductor wafer, when applying a mechanical thinning method, if the plane to be polished is very large, the variation in the thickness of the layer can be too large for useful, practical application. The inclusion of polishing stops, in accordance with embodiments of the present invention, serves to effectively reduce the size of the plane so that the variation in the thickness is reduced, even though the overall size of the plane is larger. Therefore, an acceptable range of variation can be obtained by controlling the size of and/or the distance between the polishing stops. While the polishing stops are shown generally as square or rectangular, the polishing stops according to embodiments of the present invention can be any shape, such as lines, dots, circles, triangles, or rectangles, and may be located in any suitable positions on the plane.

While the invention has been particularly shown and described with reference to the illustrated embodiments, those skilled in the art will understand that changes in form and detail may be made without departing from the spirit and scope of the invention. For example, while the semiconductor devices illustrated in the embodiments of FIGS. 14A to 23 incorporate polishing stops applied to the sapphire substrate, other embodiments of the semiconductor devices can incorporate the polishing stops applied to an epitaxial layer of the semiconductor device, as described above with reference to FIGS. 3 and 16. Accordingly, the above description is intended to provide example embodiments of the present invention, and the scope of the present invention is not to be limited by the specific examples provided.

What is claimed is:

1. A semiconductor wafer comprising:
a substrate;
a plurality of polishing stops on the substrate, the polishing stops including ceramic material;
one or more buffer layers grown on the substrate; and
one or more epitaxial layers on the one or more buffer layers.

2. The semiconductor wafer of claim 1, wherein each of the plurality of polishing stops includes boron nitride-based material.

3. The semiconductor wafer of claim 1, wherein each of the plurality of polishing stops is a multilayer polishing stop and at least one layer of each of the multilayer polishing stops includes boron nitride-based material.

4. The semiconductor wafer of claim 1, wherein each of the plurality of polishing stops is a multilayer polishing stop and at least one layer each of the multilayer polishing stops includes transition metal nitride material.

5. The semiconductor wafer of claim 1, wherein the plurality of polishing stops are formed using reactive-ion etching (RIE).

6. The semiconductor wafer of claim 1, wherein the plurality of polishing stops are transparent to visible light.

7. The semiconductor wafer of claim 1, wherein one of the one or more epitaxial layers is an adjacent layer having a refractive index, the adjacent layer being adjacent to the plurality of polishing stops, and wherein each of the plurality of polishing stops has a refractive index lower than the refractive index an adjacent semiconductor layer.

8. The semiconductor wafer of claim 1, wherein each of the polishing stops includes a conformal layer applied to an associated polishing stop, and wherein each of the plurality of polishing stops includes boron nitride and each of the plurality of conformal layers is made from a semiconductor or dielectric material.

9. The semiconductor wafer of claim 6, wherein each of the conformal layers covers at least one side of the associated polishing stop.

10. The semiconductor wafer of claim 1, wherein the plurality of polishing stops comprise a light enhancement layer.

11. A light emitting diode comprising:
a substrate;
a plurality of semiconductor layers grown on the substrate, wherein the plurality of semiconductor layers includes at least one active layer and a plurality of polishing stops, each of the plurality of polishing stops including ceramic material; and
one or more electrodes applied to one or more of the plurality of semiconductor layers.

12. The light emitting diode of claim 11, wherein the plurality of polishing stops includes boron nitride-based material.

13. The light emitting diode of claim 11, wherein each of the plurality of polishing stops is a multilayer polishing stop and at least one layer of each of the multilayer polishing stops includes boron nitride-based material.

14. The light emitting diode of claim 11, wherein each of the plurality of polishing stops is a multilayer polishing stop and at least one layer each of the multilayer polishing stops includes transition metal nitride material.

15. The light emitting diode of claim 11, wherein one of the one or more epitaxial layers is an adjacent layer having a refractive index, the adjacent layer being adjacent to the plurality of polishing stops, and wherein each of the plurality of polishing stops has a refractive index lower than the refractive index of the adjacent layer.

16. The light emitting diode of claim 11, wherein each of the polishing stops includes a conformal layer applied to an associated polishing stop, and wherein each of the plurality of polishing stops includes boron nitride-based material and each of the plurality of conformal layers is made from a semiconductor or dielectric material.

17. The light emitting diode of claim 11, wherein each of the polishing stops comprise a pattern on a surface of the substrate, and wherein the polishing stops are light scattering elements for light extraction.

18. A method of making a semiconductor device, the method comprising:
providing a substrate;
forming a plurality of polishing stops on the substrate, each of the plurality of polishing stops including ceramic material;
growing one or more buffer layers on the substrate; and
growing one or more epitaxial layers on the one or more buffer layers.

19. The method of claim 18, wherein each of the plurality of ceramic polishing stops includes boron nitride-based material.

20. The method of claim 18, wherein the step of forming the plurality of ceramic polishing stops includes growing one or more boron nitride structures on one of the one or more epitaxial layers.

21. The method of claim 18, wherein the step of forming the plurality of ceramic polishing stops includes growing one or more boron nitride structures on the substrate.

21. The method of claim 21, further comprising etching the one or more boron nitride structures using reactive-ion etching (RIE).

22. The method of claim 21, wherein the step of growing one or more boron nitride structures includes forming holes in the substrate and growing the one or more boron nitride structures in the holes in the substrate.

23. The method of claim 18, further comprising forming a conformal layer on each of the plurality of polishing stops, and wherein each of the plurality of polishing stops includes boron nitride-based material and each of the plurality of conformal layers is made from a semiconductor or dielectric material.

24. The method of claim 18, further comprising:
affixing a second substrate to the one or more metal layers; and
removing the substrate using a mechanical thinning process.
